(19) United States
(12) Patent Application Publication
(10) Pub. No.: US 2025/0119075 A1
(43) Pub. Date: Apr. 10, 2025

(54) ENERGY HARVESTING APPARATUS

(71) Applicants: Hyundai Motor Company, Seoul (KR); Kia Corporation, Seoul (KR)

(72) Inventors: Jin Young Yoon, Gimpo-si (KR); Hong Heui Lee, Suwon-si (KR); Dong Eun Cha, Hwaseong-si (KR); Dong Ha Kim, Gwacheon-si (KR); Je Yeop Lim, Gyeongsan-si (KR); Bo Hwan Cha, Gyeongsan-si (KR)

(21) Appl. No.: 18/604,766

(22) Filed: Mar. 14, 2024

(30) Foreign Application Priority Data
Oct. 5, 2023 (KR) 10-2023-0132747

(51) Int. Cl. H02N 2/18; B60K 16/00; H10N 30/30

(52) U.S. Cl. CPC H02N 2/185; H02N 2/183; H10N 30/306; B60K 2016/006

(57) ABSTRACT

In an embodiment, an energy harvesting apparatus includes a housing, a blade, and a power generation unit, which may include a power generation motor and a piezoelectric power generator. In the energy harvesting apparatus according to an embodiment, electrical energy can be generated by rotation of a blade by a slipstream generated during travel of a mobility vehicle. Electrical energy can be additionally generated by pressure and impact generated during rotation of the blade. When the blade is rotated at high speed as the driving speed of the mobility vehicle increases, pressure and impact can be reduced, thereby preventing damage to the blade or a piezoelectric element and thus improving the durability thereof.

### CROSS-REFERENCE TO RELATED APPLICATIONS

This application claims the benefit of Korean Patent Application No. 10-2023-0132747, filed on Oct. 5, 2023, which application is hereby incorporated herein by reference.

### TECHNICAL FIELD

The present disclosure relates to an energy harvesting apparatus of a mobility vehicle.

### BACKGROUND

There are various ways to produce energy required to drive transportation vehicles such as trains, automobiles, and ships, and research on new energy such as hydrogen energy, solar energy, and wind energy is continuously being conducted.

Such new energy is typical eco-friendly energy that is applicable to transportation means, and research is being actively conducted to apply the same to hydrogen vehicles and electric vehicles equipped with batteries having improved functions. However, vehicles using hydrogen energy have drawbacks in that charging is necessary and costly.

On the other hand, systems using wind energy or solar energy do not require recharging and are easy to manage. In particular, as depletion of fossil energy resources and environmental pollution caused by fossil energy are accelerated, wind and solar are attracting attention as new renewable alternative and eco-friendly energy sources.

Various means of transportation, such as trains, automobiles, ships, and aircraft, induce a slipstream around the same while operating, and can be provided with wind power generating devices using a slipstream.

Typically, a wind power generating device generates electrical energy through electricity-generating operation of a motor using rotation of a fan. However, it is difficult to generate a sufficient amount of electrical energy using the wind power generating device. Further, when a large number of fans is mounted therein, the wind power generating device may be undesirably increased in volume.

Further, the wind power generating device may generate electrical energy by rotating a fan using a slipstream. The wind power generating device may be configured such that, as the travel speed of a mobility vehicle increases, the rotational speed of the fan also increases. However, the conventional wind power generating device has no structure or method for preventing the fan from being damaged due to high-speed rotation thereof.

The information disclosed in this Background section is only for enhancement of understanding of the general background of the disclosure, and should not be taken as an acknowledgement or any form of suggestion that this information forms the related art already publicly known.

### SUMMARY

The present disclosure relates to an energy harvesting apparatus that generates electrical energy using a slipstream induced during travel of a mobility vehicle.

Embodiments of the present disclosure have been made in view of the above problems. An embodiment of the present disclosure can provide an energy harvesting apparatus that generates electrical energy using a slipstream induced during travel of a mobility vehicle and maximizes efficiency of generating electrical energy using a slipstream.

In accordance with an embodiment of the present disclosure, the above and other advantages can be accomplished by the provision of an energy harvesting apparatus including a housing, which is divided into a flow space in which air flows and a power generation space for generation of electricity and is provided therein with a rotating shaft configured to penetrate the flow space and the power generation space, a blade, which is provided in the flow space to be coupled to the rotating shaft and is configured to be rotated by the flow of air, and a power generation unit, which is provided in the power generation space and includes a pressure generator coupled to the rotating shaft and configured to be rotated together therewith, and a power generator fixed in the power generation space and configured to generate electrical energy when the pressure generator rotates and strikes the power generator.

In the housing, the flow space and the power generation space may be located on a straight line. The flow space may be provided with an inlet and an outlet for flow of air, and the power generation space may be configured to be blocked from the outside.

The housing may be further provided with a power generation motor to which the rotating shaft is coupled, and the power generation motor may be configured to convert rotational power of the rotating shaft into electrical energy.

The pressure generator may include a guide member and a striking member. The guide member may be coupled to the rotating shaft and configured to be rotated together therewith, and the striking member may be movably provided on the guide member and may include a striking protrusion.

The inner circumferential surface of the striking member and the outer circumferential surface of the guide member may be configured to be partially angled and configured to match each other.

The striking protrusion of the striking member may be provided in plural, and the plurality of striking protrusions may be configured to be spaced apart from each other in a longitudinal direction and a rotational direction.

The power generation space in the housing may be divided into a first space and a second space. The power generator may be located in the first space, the guide member may be configured to extend from the first space to the second space, and the striking member may be moved along the guide member by centrifugal force according to the rotational speed of the rotating shaft, whereby a contact position between the striking protrusion and the power generator may be changed.

The striking member may further include a weight body and an elastic body. The weight body may be on the striking member and configured to be rotated together therewith and may be spaced apart from the striking protrusion, and the elastic body may be provided in the second space to elastically support the striking member toward the first space.

The guide member may include a plurality of steps formed on the outer circumferential surface thereof, and the striking member may include a latching protrusion formed on the inner circumferential surface thereof configured to be selectively caught by one of the plurality of steps.

The striking protrusion may be provided in plural, and the plurality of striking protrusions may be formed on the outer circumferential surface of the striking member. A separation distance between the plurality of striking protrusions may be equal to a separation distance between the plurality of steps.

The housing may be provided in plural, the rotating shaft may extend to penetrate the plurality of housings, and the blade and the power generation unit may share the rotating shaft to generate electrical energy.

### BRIEF DESCRIPTION OF THE DRAWINGS

The above and other features and advantages of the present disclosure can be more clearly understood from the following detailed description taken in conjunction with the accompanying drawings, in which:

FIG. 1 is a top view showing a mobility vehicle to which an energy harvesting apparatus according to an embodiment of the present disclosure is applied;

FIG. 2 is a perspective view showing an energy harvesting apparatus according to an embodiment of the present disclosure;

FIG. 3 is a partially transparent view showing the energy harvesting apparatus shown in FIG. 2;

FIG. 4 is an exploded view of the energy harvesting apparatus shown in FIG. 2;

FIG. 5 is a cross-section view showing an initial position of the energy harvesting apparatus according to an embodiment of the present disclosure;

FIG. 6 is a perspective view for illustrating an initial position of the energy harvesting apparatus according to an embodiment of the present disclosure;

FIG. 7 is a cross-section view showing a state in which a great amount of slipstream is introduced into the energy harvesting apparatus according to an embodiment of the present disclosure;

FIG. 8 is a perspective view for illustrating a state in which a great amount of slipstream is introduced into the energy harvesting apparatus according to an embodiment of the present disclosure;

FIG. 9 is a perspective view showing an energy harvesting apparatus according to an embodiment of the present disclosure; and

FIG. 10 is a cut-away view showing an internal configuration of the energy harvesting apparatus shown in FIG. 9.

### DETAILED DESCRIPTION OF ILLUSTRATIVE EMBODIMENTS

Embodiments of the present specification will be described in detail with reference to the accompanying drawings, and same or similar elements can be denoted by same reference numerals even though they may be depicted in different drawings, and redundant descriptions thereof can be omitted.

With respect to constituent elements, the suffixes “module” and “unit” can be used in consideration of facilitating description, and do not necessarily have mutually distinguished meanings or functions.

In the following description of the embodiments of the present specification, a detailed description of known functions and configurations incorporated herein can be omitted when the same may make the subject matter of the embodiments disclosed in the present specification unclear. In addition, the accompanying drawings are provided for a better understanding of the embodiments of the present specification and are not necessarily intended to limit the technical ideas disclosed in the present specification. Therefore, it can be understood that an embodiment can include all modifications, equivalents, and substitutions within the scope and spirit of the present disclosure.

It can be understood that although the terms “first,” “second,” etc., may be used herein to describe various components, these components are not necessarily limited by these terms. These terms can be used to distinguish one component from another component.

It can be understood that when a component is referred to as being “connected to” or “coupled to” another component, it may be directly connected to or coupled to another component, or intervening components may be present. On the other hand, when a component is referred to as being “directly connected to” or “directly coupled to” another component, there are no intervening components present.

As used herein, the singular form can be intended to include the plural forms as well, unless the context clearly indicates otherwise.

It can be further understood that the terms “comprises,” “comprising,” “includes,” and/or “including,” when used herein, specify the presence of stated features, integers, steps, operations, elements, components, or combinations thereof, but do not preclude the presence or addition of one or more other features, integers, steps, operations, elements, components, or combinations thereof.

An energy harvesting apparatus according to an embodiment of the present disclosure will be described with reference to the accompanying drawings.

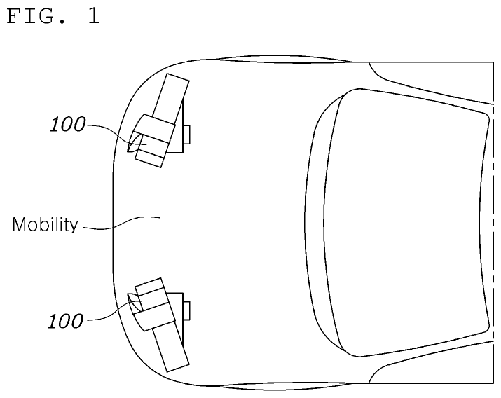

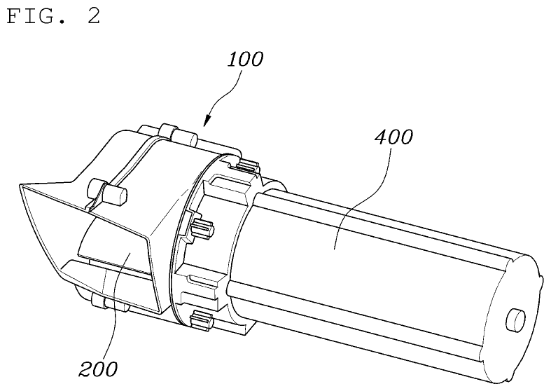

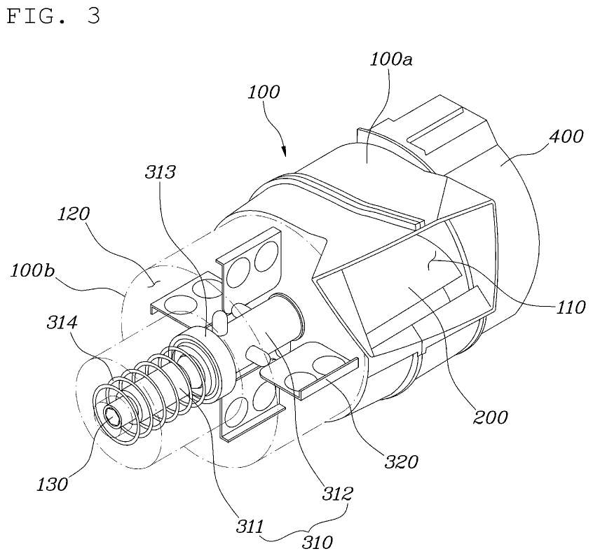

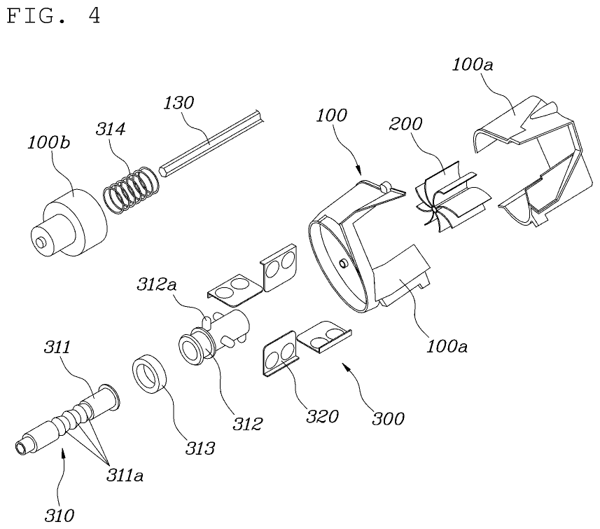

As shown in FIGS. 1 to 4, an energy harvesting apparatus according to an embodiment of the present disclosure includes a housing 100, which is divided into a flow space 110, in which air flows, and a power generation space 120 for generation of electricity, and is provided therein with a rotating shaft 130 configured to penetrate the flow space 110 and the power generation space 120, a blade 200, which is provided in the flow space 110, is coupled to the rotating shaft 130 and is configured to be rotated by the flow of air, and a power generation unit 300, which is provided in the power generation space 120 and includes a pressure generator 310 coupled to the rotating shaft 130 and configured to be rotated together therewith, and a power generator 320 fixed in the power generation space 120 and configured to generate electrical energy when the pressure generator 310 rotates and strikes the power generator 320.

The housing 100 may be further provided with a power generation motor 400 to which the rotating shaft 130 is coupled. The power generation motor 400 can convert rotational power of the rotating shaft 130 into electrical energy.

The energy harvesting apparatus of the present disclosure can be an apparatus that generates electrical energy using a slipstream induced during travel of a mobility vehicle. The energy harvesting apparatus of the present disclosure may be located in a place in a mobility vehicle into which a slipstream may be introduced, such as a front side or roof of the mobility vehicle.

For example, as shown in FIG. 1, the housing 100 may be located at the front side of the mobility vehicle. To avoid interference with other parts of the mobility vehicle, the housing 100 may be provided in a pair, and the pair of housings 100 may be located on both sides of the front bumper of the mobility vehicle.

The inner space in the housing 100 can be divided into the flow space 110 and the power generation space 120. The housing 100 may include a case 100a having the flow space 110 defined therein, and a cover 100b coupled to the case 100a and having the power generation space 120 defined therein.

The rotating shaft 130 can penetrate the flow space 110 and the power generation space 120 in the housing 100, and the blade 200 and the power generation unit 300 can be connected to the rotating shaft 130.

In the housing 100, the flow space 110, the power generation space 120, and the power generation motor 400 can be located on a straight line so that the single rotating shaft 130 can be connected to the blade 200, the power generation unit 300, and the power generation motor 400.

The flow space 110 can be provided with an inlet and an outlet for flow of air. During travel of the mobility vehicle, a slipstream may enter the flow space 110 through the inlet, and may escape from the flow space 110 through the outlet after rotating the blade 200. The housing 100 may be configured such that the inlet of the flow space 110 is oriented in the travel direction of the mobility vehicle and the outlet of the flow space 110 is oriented in a direction opposite the travel direction of the mobility vehicle.

The power generation space 120 can be configured to be blocked from the outside to prevent external contamination of the power generation unit 300 provided therein.

The blade 200 can be located in the flow space 110 in the housing 100, the power generation unit 300 can be located in the power generation space 120 in the housing 100, and the power generation motor 400 can be mounted outside the housing 100. Accordingly, the blade 200, the power generation unit 300, and the power generation motor 400 may be connected to each other via the single rotating shaft 130 and configured to be interlocked with each other.

Further, because the blade 200, the power generation unit 300, and the power generation motor 400 are positioned on a straight line along the rotating shaft 130 and the rotating shaft 130 is rotated by rotation of the blade 200 by the flow of air, the power generation motor 400 generates electrical energy using the rotational force, and the power generation unit 300 operates in the manner of being interlocked with rotation of the rotating shaft 130 and generates electrical energy in a piezoelectric manner.

As described above, the power generation unit 300 includes the pressure generator 310 and the power generator 320. The pressure generator 310 is coupled to the rotating shaft 130 and configured to be rotated together therewith. The power generator 320 generates electrical energy by being struck by the pressure generator 310 that is rotated in the state of being fixed in the power generation space 120. The pressure generator 310 may include a striking structure, and the power generator 320 may be implemented as a piezoelectric element.

Piezoelectric energy harvesting using a piezoelectric element converts mechanical energy, such as vibration, pressure, or impact, into electrical energy. When the pressure generator 310 is rotated together with the rotating shaft 130 and strikes the power generator 320, the power generator 320 may generate electrical energy.

In this way, according to the present disclosure, when the blade 200 provided in the housing 100 is rotated by a slipstream, both the power generation motor 400 and the power generation unit 300 connected to the rotating shaft 130 generate electrical energy, whereby efficiency of generating electrical energy may be improved.

The pressure generator 310 includes a guide member 311 and a striking member 312. The guide member 311 may be coupled to the rotating shaft 130 and configured to be rotated together therewith, and the striking member 312 may be movably provided on the guide member 311, and may include a striking protrusion 312a.

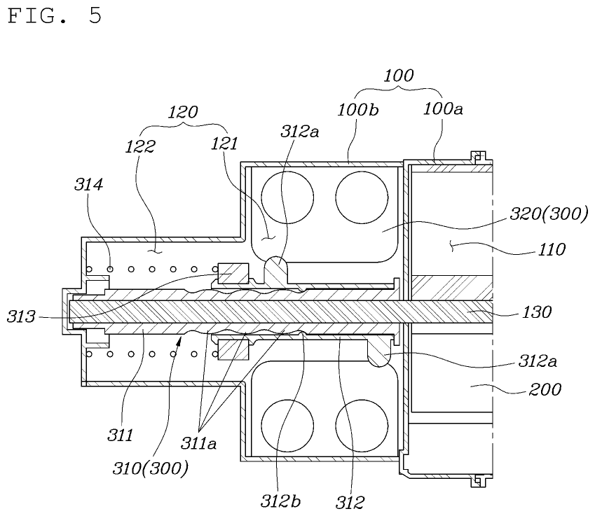

As shown in FIG. 5, the power generation unit 300 includes the pressure generator 310 and the power generator 320.

The power generation unit 320 may be implemented as a piezoelectric element, and may be provided in plural in the power generation space 120 in the housing 100.

The pressure generator 310 includes a guide member 311 and a striking member 312. The guide member 311 is connected to the rotating shaft 130 and configured to be rotated together therewith, and the striking member 312 is connected to the guide member 311 and configured to be rotated together therewith.

To this end, the rotating shaft 130 and the guide member 311 may be coupled to each other. Alternatively, the outer circumferential surface of the rotating shaft 130 and the inner circumferential surface of the guide member 311, which are in contact with each other, may be configured to be partially angled, whereby the rotating shaft 130 and the guide member 311 may be rotated together.

The striking member 312 needs to be moved in the longitudinal direction of the guide member 311 while being rotated together with the guide member 311. The inner circumferential surface of the striking member 312 and the outer circumferential surface of the guide member 311 may be configured to be partially angled so that the striking member 312 is moved along the guide member 311 while being rotated together with the guide member 311.

Accordingly, when the pressure generator 310 is rotated at high speed together with the rotating shaft 130, the striking member 312 is moved along the guide member 311 and configured to be separated from the power generator 320, thereby avoiding damage to the power generator 320.

In detail, the striking member 312 may include a plurality of striking protrusions 312a, and the striking protrusions 312a may be configured to be spaced apart from each other in the longitudinal direction and the rotational direction.

That is, the striking protrusions 312a are spaced apart from each other in the longitudinal direction of the striking member 312, and are also spaced apart from each other and configured to not overlap each other in the rotational direction of the striking member 312, whereby the number of strikes impacted on the power generator 320 by rotation of the striking member 312 may be increased.

For example, the striking protrusions 312a may be four in number. The four striking protrusions 312a may be spaced apart from each other at regular intervals in the longitudinal direction of the striking member 312, and may be spaced 90 degrees apart from each other in the rotational direction of the striking member 312. The number of striking protrusions 312a may be determined depending on the amount of electrical energy generated by the power generator 320 and the durability of the power generator 320.

In addition, because the striking member 312 can be movably provided on the guide member 311, the number of striking protrusions 312a that contact the power generator 320 may be changed depending on a position to which the striking member 312 is moved along the guide member 311.

As illustrated in FIG. 5, the power generation space 120 in the housing 100 can be divided into a first space 121 and a second space 122, the power generator 320 can be located in the first space 121, and the guide member 311 can be configured to extend across the first space 121 and the second space 122. The striking member 312 can be moved along the guide member 311 by centrifugal force according to the rotational speed of the rotating shaft 130, whereby contact positions between the striking protrusions 312a and the power generator 320 may be changed.

As illustrated in FIG. 5, the power generation space 120 in the housing 100 can include a first space 121 in which the power generator 320 is located and a second space 122 that is an extra space for reception of the striking member 312 separated from the power generator 320.

The guide member 311 can be coupled to the rotating shaft 130 and configured to extend across the first space 121 and the second space 122, whereby the striking member 312 can be moved along the guide member 311 from the first space 121 to the second space 122, and vice versa.

When the striking member 312 is located in the first space 121 of the power generation space 120 in the housing 100, the striking member 312 can contact and strike the power generator 320 so that the power generator 320 generates electrical energy. When the striking member 312 is moved to the second space 122 of the power generation space 120 in the housing 100, the striking member 312 can be separated from the power generator 320, or the number of contact points between the striking member 312 and the power generator 320 can be reduced.

In particular, the striking member 312 may be moved along the guide member 311 by centrifugal force according to the rotational speed of the rotating shaft 130.

The rotating shaft 130 can be rotated together with the blade 200 according to the amount of air flowing in the flow space 110 in the housing 100. As the driving speed of the mobility vehicle increases, the rotation amount of the blade 200 can increase, and the rotational speed of the rotating shaft 130 can also increase.

If the striking member 312 rotating at high speed together with the rotating shaft 130 continuously or repeatedly strikes the power generator 320, external stress applied to the power generator 320 can increase, and can lead to damage to the power generator 320 (i.e., deterioration in the durability of the power generator 320).

As the rotational speed of the rotating shaft 130 increases, the striking member 312 can be gradually moved along the guide member 311 in a direction away from the power generator 320 by centrifugal force, and thus the number of contact points between the striking protrusions 312a of the striking member 312 and the power generator 320 can be reduced, thereby damage to the power generator 320 can be avoided.

The striking member 312 can further include a weight body 313 and an elastic body 314.

The weight body 313 may be made of metal or rubber, and may be on the striking member 312 and can be configured to be rotated together with the striking member 312. In addition, the weight body 313 may be spaced apart from the striking protrusions 312a of the striking member 312 and may be on a portion of the striking member 312 that is located in the second space 122.

The elastic body 314 can be located in the second space 122 to elastically support or force the striking member 312 toward the first space 121. The elastic body 314 may be implemented as a spring, and may be connected to or in contact with the weight body 313 or the striking member 312 in a bearing structure. Accordingly, the elastic body 314 may allow the striking member 312 to be rotated relative thereto while elastically supporting or biasing the striking member 312.

Accordingly, as the rotational speed of the rotating shaft 130 coupled to the pressure generator 310 increases, the weight body 313 on the striking member 312 may be moved from the first space 121 to the second space 122 by centrifugal force.

When the striking member 312 is located at the initial position, all of the striking protrusions 312a can contact the power generator 320, and as the striking member 312 is moved to the second space 122 in proportion to increase in the rotational speed thereof, the number of striking protrusions 312a contacting the power generator may be gradually reduced. On the other hand, as the rotational speed of the striking member 312 decreases, the striking member 312 may be returned from the second space 122 to the first space 121 by the elastic support force of the elastic body 314.

In addition, the guide member 311 may include a plurality of curved protrusions or steps 311a formed on the outer circumferential surface thereof, and the striking member 312 may include a latching protrusion 312b formed on the inner circumferential surface thereof and configured to be selectively caught by one of the steps 311a.

As the moving position of the striking member 312 along the guide member 311 is changed, the position at which the latching protrusion 312b is caught by one of the steps 311a may be changed.

The moving position of the striking member 312 may be fixed step by step due to the steps 311a formed on the guide member 311.

A separation distance between the plurality of striking protrusions 312a formed on the outer circumferential surface of the striking member 312 may be equal to or corresponding to a separation distance between the steps 311a.

Accordingly, depending on a position at which the latching protrusion 312b of the striking member 312 is caught or bound by one of the steps 311a of the guide member 311, the position of each of the striking protrusions 312a contacting the power generator 320 may be adjusted step by step.

For example, as illustrated in FIGS. 5 to 9, four striking protrusions 312a may be formed on the outer circumferential surface of the striking member 312, three steps 311a may be formed on the guide member 311, and the latching protrusion 312b of the striking member 312 may be configured to be caught or bound by one of the steps 311a of the guide member 311.

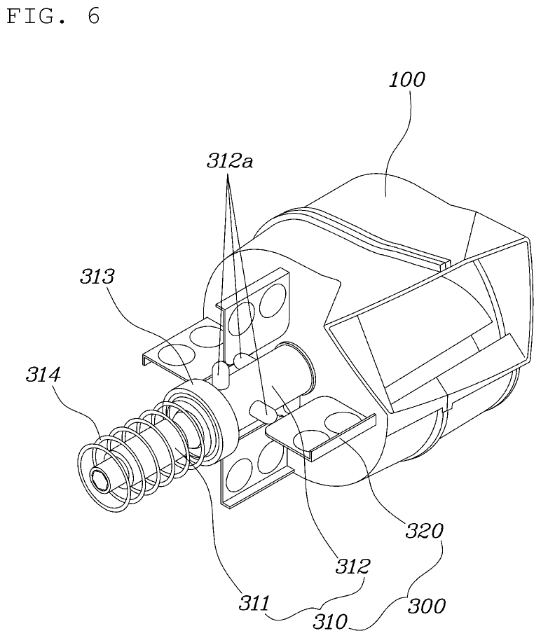

As illustrated in FIGS. 5 and 6, when the striking member 312 is located at an initial position, all of the striking protrusions 312a of the striking member 312 can be located and configured to be contactable with the power generator 320. Therefore, when the rotating shaft 130 is rotated, all of the striking protrusions 312a can alternately strike the power generator 320, thereby maximizing or increasing the amount of electrical energy generated by the power generator 320.

When the amount of air flowing in the flow space 110 in the housing 100 increases and thus the rotational speeds of the blade 200 and the rotating shaft 130 increase, the striking member 312 may be moved along the guide member 311, and accordingly, the position at which the latching protrusion 312b is caught or bound by one of the steps 311a may be changed.

As the latching protrusion 312b of the striking member 312 is sequentially caught or bound by the steps 311a of the guide member 311, the striking member 312 may be moved step by step, and thus the number of contact points between the striking protrusions 312a and the power generator 320 may be adjusted step by step.

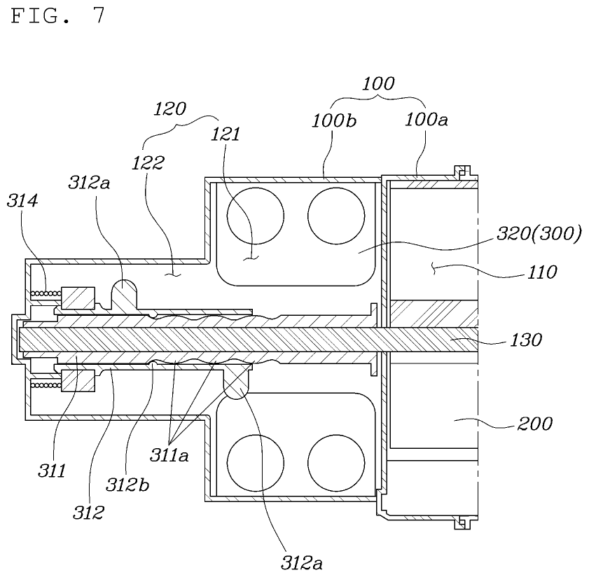

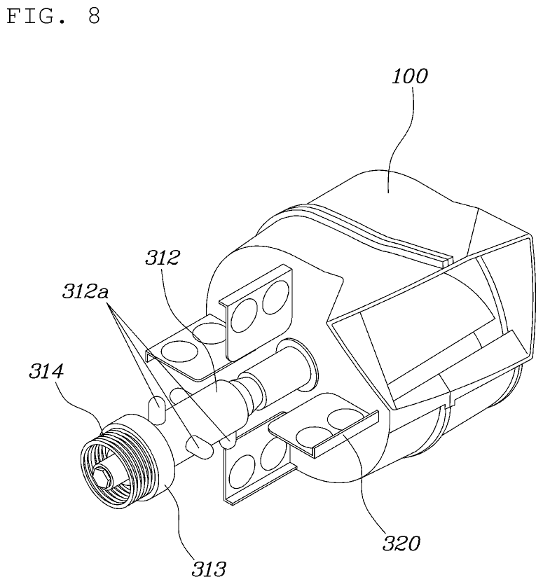

As the rotational speed of the rotating shaft 130 increases, the striking member 312 may be moved along the guide member 311. When the rotational speed of the rotating shaft 130 exceeds a set, selected, or predetermined level, as shown in FIGS. 7 and 8, the striking member 312 may be moved in a direction away from the power generator 320, and as a result, only one striking protrusion 312a may contact the power generator 320.

External stress applied to the power generator 320 due to contact with the striking member 312 may be adjusted depending on the rotational speed of the rotating shaft 130. Accordingly, the fatigue life of the power generator 320 may be reduced, and consequently, the durability of the pressure generator 310 and the power generator 320 may be improved.

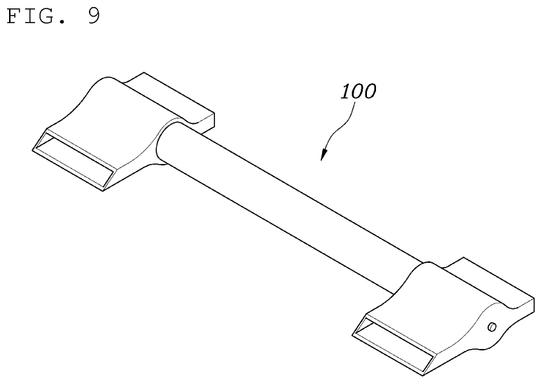

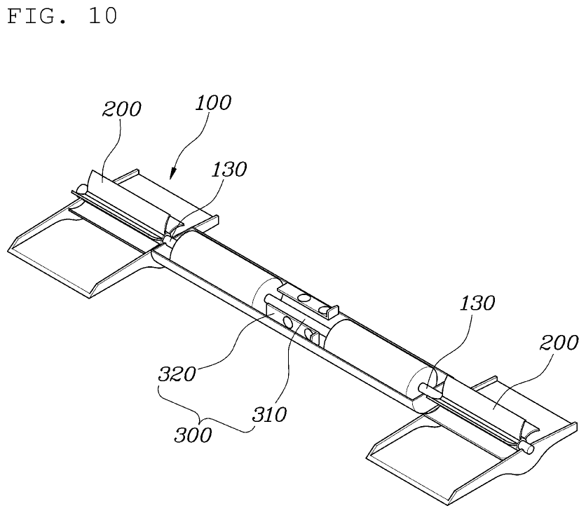

According to an embodiment of the present disclosure, as shown in FIGS. 9 and 10, the housing 100 may be provided in plural, the rotating shaft 130 may extend to penetrate the plurality of housings 100, and the blade 200 and the power generation unit 300 may share the rotating shaft 130 to generate electrical energy.

Because the housing 100 is provided in plural, the blade 200 may be provided in plural, and the plurality of blades 200 may be located in the plurality of housings 100, respectively. Further, because the single rotating shaft 130 penetrates the plurality of housings 100, the plurality of blades 200 and the power generation unit 300 may be connected to each other via the single rotating shaft 130.

Accordingly, the amount of air flowing into the flow spaces 110 in the housings 100 may be increased, and thus the rotation amount of the blades 200 may be secured. Further, because the components are connected to each other via the single rotating shaft 130, it may be possible to simplify the structure of the apparatus.

The housings 100 may be located at a mounting position of an active air flap in the front side of the mobility vehicle to selectively generate electricity.

As can be apparent from the above description, according to an embodiment for an energy harvesting apparatus structured as described above, electrical energy can be generated by rotation of the blade by a slipstream generated during travel of the mobility vehicle. Further, electrical energy can be additionally generated by pressure and impact generated during rotation of the blade. Accordingly, the amount of electrical energy generated can be increased.

In addition, when the blade is rotated at high speed as the driving speed of the mobility vehicle increases, pressure and impact can be reduced, thereby preventing damage to the blade or the piezoelectric element and thus improving the durability thereof.

Although the embodiments of the present disclosure have been disclosed for illustrative purposes, those skilled in the art can appreciate that various modifications, additions, and substitutions are possible, without departing from the scope and spirit of the accompanying claims.

What is claimed is:

1. An energy harvesting apparatus comprising:
a housing divided into a flow space configured for air to flow in, and a power generation space configured for generation of electricity, the housing being provided therein with a rotatable shaft that penetrates the flow space and the power generation space;
a blade in the flow space coupled to the rotatable shaft, the blade being configured to be rotated by flow of air; and
a power generation unit in the power generation space, the power generation unit comprising a pressure generator coupled to the rotatable shaft and configured to be rotated together therewith, and a power generator fixed in the power generation space, the power generator being configured to generate electrical energy when the pressure generator rotates and strikes the power generator.

2. The apparatus of claim 1, wherein the flow space in the housing and the power generation space are located on a straight line,
wherein the flow space includes an inlet and an outlet for flow of air, and
wherein the power generation space is configured to be blocked from an outside.

3. The apparatus of claim 1, wherein the housing further includes a power generation motor to which the rotatable shaft is coupled, and wherein the power generation motor is configured to convert rotational power of the rotatable shaft into electrical energy.

4. The apparatus of claim 1, wherein the pressure generator comprises a guide member and a striking member,
wherein the guide member is coupled to the rotatable shaft so as to be rotated together therewith, and
wherein the striking member is movably provided on the guide member and comprises a striking protrusion.

5. The apparatus of claim 4, wherein an inner circumferential surface of the striking member and an outer circumferential surface of the guide member are configured to be partially angled and configured to engage each other.

6. The apparatus of claim 4, wherein the striking protrusion of the striking member is provided in plural, and the plurality of striking protrusions is configured to be spaced apart from each other in a longitudinal direction and a rotational direction.

7. The apparatus of claim 4, wherein the power generation space in the housing is divided into a first space and a second space,
wherein the power generator is in the first space,
wherein the guide member is configured to extend from the first space to the second space, and
wherein the striking member is configured to move along the guide member by centrifugal force according to a rotational speed of the rotatable shaft, such that a contact position between the striking protrusion and the power generator is changed.

8. The apparatus of claim 7, wherein the striking member further comprises a weight body and an elastic body,
wherein the weight body is on the striking member and configured to be rotated together therewith and is spaced apart from the striking protrusion, and
wherein the elastic body is in the second space and configured to elastically bias the striking member toward the first space.

9. The apparatus of claim 4, wherein the guide member comprises a plurality of steps on an outer circumferential surface thereof, and
wherein the striking member comprises a latching protrusion on an inner circumferential surface thereof and configured to be selectively caught by one of the plurality of steps.

10. The apparatus of claim 9, wherein the striking protrusion is provided in plural, and the plurality of striking protrusions is on an outer circumferential surface of the striking member, and
wherein a first separation distance between the plurality of striking protrusions is equal to a second separation distance between the plurality of steps.

11. The apparatus of claim 1, wherein the housing is provided in plural,
wherein the rotatable shaft extends to penetrate the plurality of housings, and
wherein the blade and the power generation unit share the rotatable shaft.

12. An energy harvesting apparatus comprising:
a housing divided into a flow space and a power generation space;
a rotatable shaft in the housing and extending into the flow space and the power generation space;
a blade in the flow space coupled to the rotatable shaft, the blade being configured to be rotated by flow of air in the flow space and configured to rotate the rotatable shaft in response to the blade rotating; and
a power generation unit in the power generation space, wherein the power generation space in the housing is divided into a first space and a second space, and wherein the power generation unit comprises
a power generation motor coupled to the rotatable shaft, the power generation motor being configured to convert power of the rotatable shaft into electrical energy,
a piezoelectric power generator in the first space comprising piezoelectric elements, and
a pressure generator comprising a guide member and a striking member, the striking member being movably coupled to the guide member, the striking member having striking protrusions extending therefrom, the guide member being coupled to the rotatable shaft and configured to be rotated by the rotatable shaft, the guide member extending into the first space and the second space, and the striking member being configured to move between the first space and the second space relative to the guide member, such that more of the striking protrusions are aligned with the piezoelectric power generator when the striking member is in the first space than when the striking member is moved into the second space, and wherein the striking protrusions are configured to strike the piezoelectric power generator so that the piezoelectric elements of the piezoelectric power generator convert impact energy into electrical energy.

13. The apparatus of claim 12, wherein the pressure generator comprises a spring in the second space, the spring being configured to bias the striking member toward the first space.

14. The apparatus of claim 13, wherein the striking member is configured to move along the guide member by centrifugal force according to a rotational speed of the rotatable shaft, such that the spring is compressed as the rotational speed of the rotatable shaft increases, and such that a contact position between the striking protrusion and the piezoelectric power generator is changed.

15. The apparatus of claim 14, wherein the pressure generator further comprises a weight body coupled to the striking member and configured to be rotated together with the striking member, wherein the weight member is spaced apart from the striking protrusions.

16. The apparatus of claim 15, wherein the guide member comprises a plurality of steps on an outer circumferential surface thereof, and
wherein the striking member comprises a latching protrusion on an inner circumferential surface thereof and configured to be selectively caught by one of the plurality of steps on the guide member.

17. The apparatus of claim 16, wherein a first separation distance between the striking protrusions is equal to a second separation distance between the plurality of steps.

18. A method of operating an energy harvesting apparatus that comprises a housing divided into a flow space and a power generation space and having a rotatable shaft that penetrates the flow space and the power generation space, the energy harvesting unit further comprising a blade in the flow space coupled to the rotatable shaft, and a power generation unit in the power generation space, the power generation unit comprising a pressure generator coupled to the rotatable shaft and a power generator fixed in the power generation space, the method comprising:
flowing air into the flow space thereby causing the blade to be rotated by the flow of the air; and
generating electrical energy as a result of the pressure generator rotating and striking the power generator.

19. The method of claim 18, further comprising converting rotational power of the rotatable shaft into electrical energy.
